(19) United States
(12) Patent Application Publication
(10) Pub. No.: US 2025/0324853 A1
(43) Pub. Date: Oct. 16, 2025

(54) DISPLAY DEVICE

(71) Applicant: Samsung Display Co., LTD., Yongin-si (KR)

(72) Inventors: Seung Hyun LEE, Yongin-si (KR); Min Woo WOO, Yongin-si (KR); Sung Ho KIM, Yongin-si (KR); Se Wan SON, Yongin-si (KR); Jin Sung AN, Yongin-si (KR); Wang Woo LEE, Yongin-si (KR); Hye Ri CHO, Yongin-si (KR)

(21) Appl. No.: 18/915,231

(22) Filed: Oct. 14, 2024

(30) Foreign Application Priority Data
Apr. 16, 2024 (KR) 10-2024-0050580

(51) Int. Cl. H10K 59/122; H10K 59/131

(52) U.S. Cl. CPC H10K 59/122; H10K 59/131

(57) ABSTRACT

A display device includes a substrate including a light emitting area and a non-light emitting area, a connection electrode positioned on the substrate, an anode electrode positioned on the connection electrode in a portion overlapping the light emitting area, a cathode electrode on the anode electrode, a pixel defining layer positioned on the connection electrode in a portion overlapping the non-light emitting area and defining a first opening, and a bank structure positioned on the pixel defining layer and including a first bank layer and a second bank layer, wherein the first bank layer is electrically connected to the connection electrode through a bank contact hole.

### CROSS-REFERENCE TO RELATED APPLICATION

The present application claims priority to and the benefit of Korean Patent Application No. 10-2024-0050580, filed on Apr. 16, 2024, in the Korean Intellectual Property Office, the entire disclosure of which is incorporated herein by reference.

### BACKGROUND

### 1. Field

Aspects of the present disclosure relate to a display device.

### 2. Description of the Related Art

As an information society develops, the demand for a display device for displaying an image is increasing in various forms. For example, the display device has been applied to various electronic devices such as smartphones, digital cameras, laptop computers, navigation devices, and smart televisions. The display devices may be flat panel display devices such as liquid crystal display devices, field emission display devices, or organic light emitting display devices. Among the flat panel display devices, the light emitting display device may include a light emitting element in which each of the pixels of a display panel may emit light by itself, thereby displaying an image without a backlight unit providing the light to the display panel.

As various electronic devices have recently developed, the demand for display devices with high aperture ratio and high resolution is increasing. Because high pixel integration is required for the display devices with high aperture ratio and high resolution, a display device that meets such requirements and a method of fabricating the display device is desired.

The above information disclosed in this Background section is only for enhancement of understanding of the background of the invention and therefore it may contain information that does not form the prior art.

### SUMMARY

Aspects of the present disclosure are directed to a high-resolution display device.

Aspects of the present disclosure are also directed to a display device that substantially reduces (e.g., solves) light emission defects in a pixel.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

Details of other embodiments are included in the detailed description and drawings.

According to some embodiments of the present disclosure, there is provided a display device including: a substrate including a light emitting area and a non-light emitting area; a connection electrode positioned on the substrate; an anode electrode positioned on the connection electrode in a portion overlapping the light emitting area; a cathode electrode on the anode electrode; a pixel defining layer positioned on the connection electrode in a portion overlapping the non-light emitting area and defining a first opening; and a bank structure positioned on the pixel defining layer and including a first bank layer and a second bank layer, wherein the first bank layer is electrically connected to the connection electrode through a bank contact hole.

In some embodiments, the second bank layer includes a tip that protrudes more toward the first opening than a side surface of the first bank layer facing the light emitting area.

In some embodiments, the connection electrode includes: a first portion overlapping the light emitting area and not overlapping the non-light emitting area; and a second portion overlapping the non-light emitting area and not overlapping the light emitting area.

In some embodiments, the first portion and the second portion are spaced apart from each other.

In some embodiments, the connection electrode includes a conductive metal.

In some embodiments, the first portion and the second portion are formed at the same layer in a direction parallel to the substrate.

In some embodiments, the first portion and the second portion are formed on different layers in a direction parallel to the substrate.

In some embodiments, the first bank layer is in contact with the second portion through the bank contact hole, and the anode electrode is in contact with the first portion through an anode contact hole.

In some embodiments, the cathode electrode is in contact with the first bank layer, and the cathode electrode and the first bank layer are electrically connected to each other.

In some embodiments, the cathode electrode is electrically connected to the second portion through the first bank layer.

In some embodiments, the first bank layer has higher electrical conductivity than the second bank layer.

In some embodiments, the first bank layer includes aluminum, and the second bank layer includes titanium.

In some embodiments, the pixel defining layer is positioned to surround the bank contact hole.

In some embodiments, a residual pattern is positioned between the pixel defining layer and the anode electrode in a direction perpendicular to the substrate, and the residual pattern overlaps a tip of the second bank layer in the direction perpendicular to the substrate.

In some embodiments, the second bank layer includes a recessed portion recessed in a direction toward the pixel defining layer in a portion overlapping the non-light emitting area.

In some embodiments, the recessed portion of the second bank layer overlaps the bank contact hole and the connection electrode in a direction perpendicular to the substrate.

According to some embodiments of the present disclosure, there is provided a display device including: a substrate including a light emitting area and a non-light emitting area; a connection electrode positioned on the non-light emitting area of the substrate and not overlapping the light emitting area; a pixel defining layer positioned on the connection electrode and defining a first opening; a bank contact hole penetrating through the pixel defining layer; and a bank structure positioned on the pixel defining layer, defining a second opening, and filling the bank contact hole, wherein in a plan view, the bank structure completely covers the connection electrode.

In some embodiments, in a plan view, the bank structure covers a portion of the pixel defining layer.

In some embodiments, in a plan view, the pixel defining layer exposes the bank contact hole, and in a plan view, the pixel defining layer completely surrounds the connection electrode.

In some embodiments, in a plan view, the second opening completely surrounds the first opening.

The display device according to some embodiments may be provided as a high-resolution display device by including a bank structure overlapping a non-light emitting area. Further, the display device according to some embodiments may substantially reduce (e.g., solve) light emission defects in the pixel by including a separate connection electrode directly connected to the bank structure.

However, the effects of the embodiments are not restricted to the ones set forth herein. The above and other effects of the embodiments will become more apparent to one of daily skill in the art to which the embodiments pertain by referencing the claims.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view illustrating a display device according to some embodiments of the present disclosure;

FIG. 2 is a schematic cross-sectional view of the display device of FIG. 1, according to some embodiments of the present disclosure;

FIG. 3 is a plan view illustrating a display layer in FIG. 2, according to some embodiments of the present disclosure;

FIG. 4 is a plan view illustrating an arrangement of a plurality of pixels in FIG. 3, according to some embodiments of the present disclosure;

FIGS. 5 and 6 are plan views illustrating an arrangement of a plurality of pixels in FIG. 3, according to some other embodiments of the present disclosure;

FIG. 7 is a schematic cross-sectional view of the display layer taken along the line X1-X1′ of FIG. 4, according to some embodiments of the present disclosure;

FIG. 8 is an enlarged cross-sectional view of a display element layer and a thin film encapsulation layer overlapping a first light emitting area in FIG. 7, according to some embodiments of the present disclosure;

FIG. 9 is an enlarged cross-sectional view of a display element layer and a thin film encapsulation layer overlapping a non-light emitting area positioned between the first light emitting area and a third light emitting area in FIG. 7, according to some embodiments of the present disclosure;

FIG. 10 is a plan view illustrating an arrangement of a connection electrode, a pixel defining layer, and a bank structure in FIG. 9, according to some embodiments of the present disclosure;

FIG. 11 is an enlarged cross-sectional view of a display element layer and a thin film encapsulation layer overlapping a non-light emitting area positioned between the first light emitting area and the third light emitting area in FIG. 7 according to still other embodiments of the present disclosure; and

FIG. 12 is a schematic cross-sectional view taken along the line X1-X1′ of FIG. 4, according to still other embodiments of the present disclosure.

### DETAILED DESCRIPTION

The present disclosure will now be described more fully herein with reference to the accompanying drawings, in which some embodiments of the disclosure are shown. The disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

It is also to be understood that when a layer is referred to as being “on” another layer or substrate, it may be directly on the other layer or substrate, or one or more intervening layers may also be present. The same reference numbers indicate the same components throughout the specification.

It is to be understood that, although the terms “first,” “second,” etc. may be used herein to describe various elements, these elements should not be limited by these terms. These terms are used to distinguish one element from another element. For instance, a first element discussed below could be termed a second element without departing from the teachings of the disclosure. Similarly, the second element could also be termed a first element.

In addition, it will also be understood that when a layer is referred to as being “between” two layers, it can be the only layer between the two layers, or one or more intervening layers may also be present.

The terminology used herein is for the purpose of describing particular embodiments and is not intended to be limiting of the inventive concept. As used herein, the singular forms “a” and “an” are intended to include the plural forms as well, unless the context clearly indicates otherwise. It will be further understood that the terms “include,” “including,” “comprises,” “comprising,” “has,” “have,” and “having,” when used in this specification, specify the presence of stated features, integers, steps, operations, elements, and/or components, but do not preclude the presence or addition of one or more other features, integers, steps, operations, elements, components, and/or groups thereof.

As used herein, the term “and/or” includes any and all combinations of one or more of the associated listed items. For example, the expression “A and/or B” denotes A, B, or A and B. Expressions such as “one or more of” and “at least one of,” when preceding a list of elements, modify the entire list of elements and do not modify the individual elements of the list. For example, the expression “one or more of A, B, and C,” “at least one of A, B, or C,” “at least one of A, B, and C,” and “at least one selected from the group consisting of A, B, and C” indicates only A, only B, only C, both A and B, both A and C, both B and C, or all of A, B, and C.

Further, the use of “may” when describing embodiments of the inventive concept refers to “one or more embodiments of the inventive concept.” Also, the term “exemplary” is intended to refer to an example or illustration.

It will be understood that when an element or layer is referred to as being “on”, “connected to”, “coupled to”, or “adjacent” another element or layer, it can be directly on, connected to, coupled to, or adjacent the other element or layer, or one or more intervening elements or layers may be present. When an element or layer is referred to as being “directly on,” “directly connected to”, “directly coupled to”, “in contact with”, “in direct contact with”, or “immediately adjacent” another element or layer, there are no intervening elements or layers present.

As used herein, the term “substantially,” “about,” and similar terms are used as terms of approximation and not as terms of degree, and are intended to account for the inherent variations in measured or calculated values that would be recognized by those of ordinary skill in the art. Further, if the term “substantially” is used in combination with a feature that could be expressed using a numeric value, the term “substantially” denotes a range of +/−5% of the value centered on the value. Furthermore, a specific quantity or range recited in this written description or the claims may also encompass the inherent variations in measured or calculated values that would be recognized by those of ordinary skill in the art.

As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the inventive concept pertains. It is also to be understood that terms defined in commonly used dictionaries should be interpreted as having meanings consistent with the meanings in the context of the related art, and are expressly defined herein unless they are interpreted in an ideal or overly formal sense.

Hereinafter, embodiments of the present disclosure will be further described in further detail with reference to the accompanying drawings.

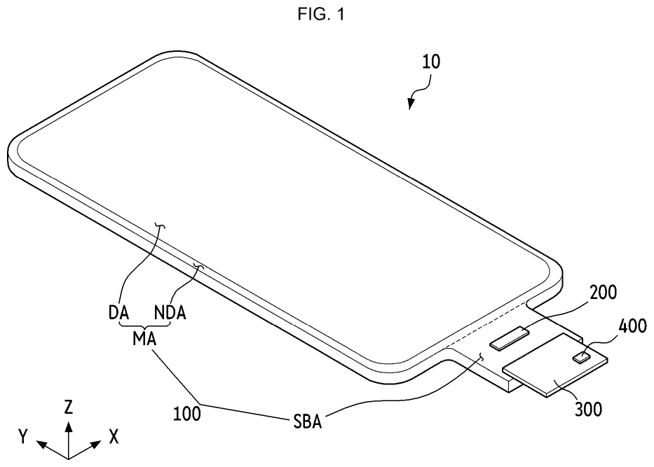

FIG. 1 is a perspective view illustrating a display device according to some embodiments of the present disclosure.

Referring to FIG. 1, a display device 10 displays a moving image or a still image. The display device 10 may refer to any electronic device that provides a display screen. For example, the display device 10 may include a television, a laptop computer, a monitor, a billboard, an internet of things device, a mobile phone, a smartphone, a tablet personal computer (PC), an electronic watch, a smartwatch, a watch phone, a head mounted display, a mobile communication terminal, an electronic notebook, an electronic book, a portable multimedia player (PMP), a navigation device, a game console, a digital camera, a camcorder, and the like that provide the display screen.

In FIG. 1, a first direction (e.g., a X-axis direction), a second direction (e.g., a Y-axis direction), and a third direction (e.g., a Z-axis direction) are defined. The first direction (e.g., the X-axis direction) and the second direction (e.g., the Y-axis direction) may be perpendicular to each other, the first direction (e.g., the X-axis direction) and the third direction (e.g., the Z-axis direction) may be perpendicular to each other, and the second direction (e.g., the Y-axis direction) and the third direction (e.g., the Z-axis direction) may be perpendicular to each other. It may be understood that the first direction (e.g., the X-axis direction) means a horizontal direction in the drawings, the second direction (e.g., the Y-axis direction) means a vertical direction in the drawings, and the third direction (e.g., the Z-axis direction) means upper and lower directions in the drawings, that is, a thickness direction. In the following specification, unless otherwise specified, the term “direction” may refer to opposing directions extending along the same line. In addition, when both “directions” extending to both sides need to be distinguished from each other, one side will be referred to as “one side in the direction” and the other side will be referred to as “the other side in the direction”. In FIG. 1, a direction in which an arrow indicating a direction is directed is referred to as one side, and an opposite direction thereof is referred to as the other side.

Hereinafter, for convenience of explanation, in referring to surfaces of each member constituting the display device 10, one surface facing one side in a direction in which an image is displayed, that is, in the third direction (e.g., the Z-axis direction) is referred to as an upper surface, and an opposite surface of the one surface is referred to as the other surface. However, the present disclosure is not limited thereto, and the one surface and the other surface of the member may be referred to as a front surface and a rear surface, respectively, or may also be referred to as a first surface or a second surface. In addition, in describing a relative position of each member of the display device 10, one side in the third direction (e.g., the Z-axis direction) may be referred to as an upper side and the other side in the third direction (e.g., the Z-axis direction) may be referred to as a lower side.

A shape of the display device 10 may be variously changed in a suitable manner. For example, the display device 10 may have a shape such as a rectangle with a long width, a rectangle with a long length, a square, a quadrangle with rounded corners (or vertices), other polygons, a circle, or the like.

The display device 10 may include a display panel 100, a display driver 200, a circuit board 300, and a touch driver 400.

The display panel 100 may include a main area MA and a sub-area SBA. The main area MA may include a display area DA including pixels displaying an image and a non-display area NDA disposed around the display area DA. The main area MA and the sub-area SBA may include a flexible material that may be bent, folded, rolled, or the like.

The display area DA is an area in which a screen may be displayed, and the non-display area NDA is an area in which a screen is not displayed. The display area DA may also be referred to as an active area, and the non-display area NDA may also be referred to as a non-active area. The display area DA may generally occupy the center of the display device 10. The non-display area NDA may be an area outside the display area DA. The non-display area NDA may be defined as an edge area of the main area MA of the display panel 100. The non-display area NDA may include lines that supply signals to the display area DA and lines connecting the display driver 200 and the display area DA.

The sub-area SBA may be an area extending from one side of the main area MA. When the sub-area SBA is bent, the sub-area SBA may overlap the main area MA in a thickness direction (e.g., a third direction (e.g., the Z-axis direction)). The sub-area SBA may include the display driver 200 and a display pad connected to the circuit board 300. In some other embodiments, the sub-area SBA may be omitted, and the display driver 200 and the display pad may be positioned in the non-display area NDA.

The display driver 200 may output signals and voltages for driving the display panel 100. The display driver 200 may be formed as an integrated circuit (IC) and mounted on the display panel 100 by a chip on glass (COG) method, a chip on plastic (COP) method, or an ultrasonic bonding method. For example, the display driver 200 may be disposed in the sub-area SBA, and may overlap the main area MA in the thickness direction by bending of the sub-area SBA. As another example, the display driver 200 may be mounted on the circuit board 300.

The circuit board 300 may be attached onto the display pad of the display panel 100 using an anisotropic conductive film (ACF). The circuit board 300 may be electrically connected to the display pad. The circuit board 300 may be a flexible film such as a flexible printed circuit board, a printed circuit board, or a chip on film.

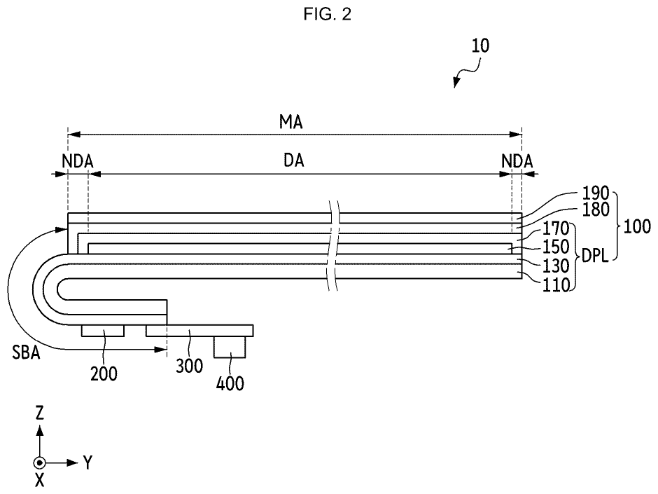

The touch driver 400 may be mounted on the circuit board 300. The touch driver 400 may be connected to a touch sensor layer (“180” in FIG. 2) of the display panel 100.

FIG. 2 is a schematic cross-sectional view of the display device of FIG. 1, according to some embodiments of the present disclosure.

Referring to FIG. 2, the display panel 100 may include a display layer DPL, a touch sensor layer 180, and a color filter layer 190. The display layer DPL may include a substrate 110, a thin film transistor layer 130, a display element layer 150, and a thin film encapsulation layer 170.

The substrate 110 may be a base substrate or a base member. The substrate 110 may be a flexible substrate that may be bent, folded, rolled, or the like. For example, the substrate 110 may include a polymer resin such as polyimide PI, but is not limited thereto. In some other embodiments, the substrate 110 may include a glass material or a metal material.

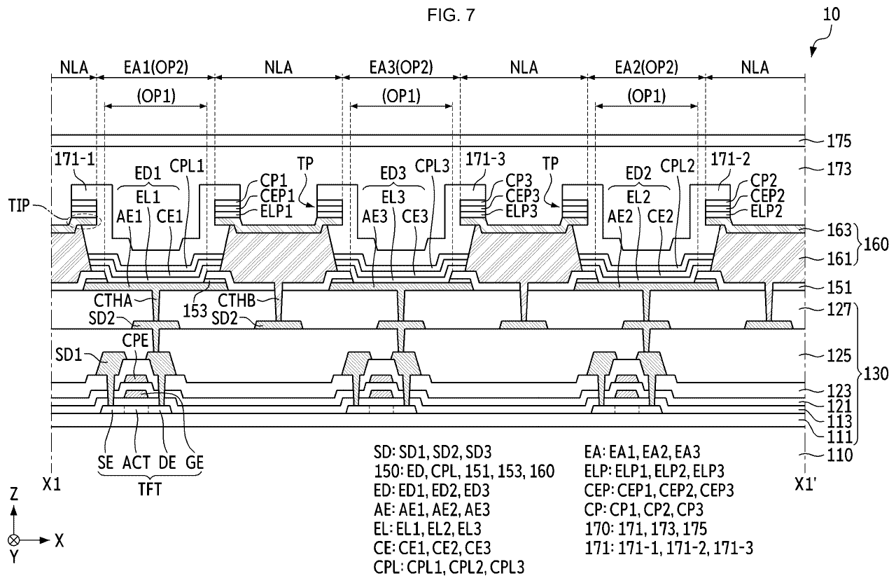

The thin film transistor layer 130 may be disposed on the substrate 110. The thin film transistor layer 130 may be positioned in a portion overlapping the display area DA, the non-display area NDA, and the sub-area SBA. The thin film transistor layer 130 may include a plurality of thin film transistors (“TFT” in FIG. 7).

The display element layer 150 may be disposed on the thin film transistor layer 130. The display element layer 150 may be positioned in a portion overlapping the display area DA. The display element layer 150 may include, but is not limited to, at least one of an organic light emitting diode (LED) including an organic light emitting layer, a quantum dot LED including a quantum dot light emitting layer, an inorganic LED including an inorganic semiconductor, and a micro LED.

The thin film encapsulation layer 170 may be positioned on the display element layer 150. The thin film encapsulation layer 170 may be positioned in a portion overlapping the display area DA and the non-display area NDA. The thin film encapsulation layer 170 may cover an upper surface and side surfaces of the display element layer 150, and may protect the display element layer 150 from external oxygen and moisture. The thin film encapsulation layer 170 may include at least one inorganic film and at least one organic film for encapsulating the display element layer 150.

The touch sensor layer 180 may be disposed on the thin film encapsulation layer 170. The touch sensor layer 180 may be positioned in a portion overlapping the display area DA and the non-display area NDA. The touch sensor layer 180 may sense a user's touch in a mutual capacitance method or a self-capacitance method.

The color filter layer 190 may be disposed on the touch sensor layer 180. The color filter layer 190 may be positioned in a portion overlapping the display area DA and the non-display area NDA. The color filter layer 190 may absorb a portion of light introduced from the outside of the display device 10 to reduce reflected light caused by external light. Therefore, the color filter layer 190 may prevent color distortion caused by reflection of external light.

As the color filter layer 190 is directly disposed on the touch sensor layer 180, the display device 10 may not require a separate substrate for the color filter layer 190. Therefore, the display device 10 may have a relatively small thickness. The color filter layer 190 may also be omitted depending on the embodiment.

As illustrated in FIG. 2, a portion of the display layer DPL overlapping the sub-area SBA may be bent. When a portion of the display layer DPL is bent, the display driver 200, circuit board 300, and touch driver 400 may overlap the main area MA in the third direction (e.g., the Z-axis direction).

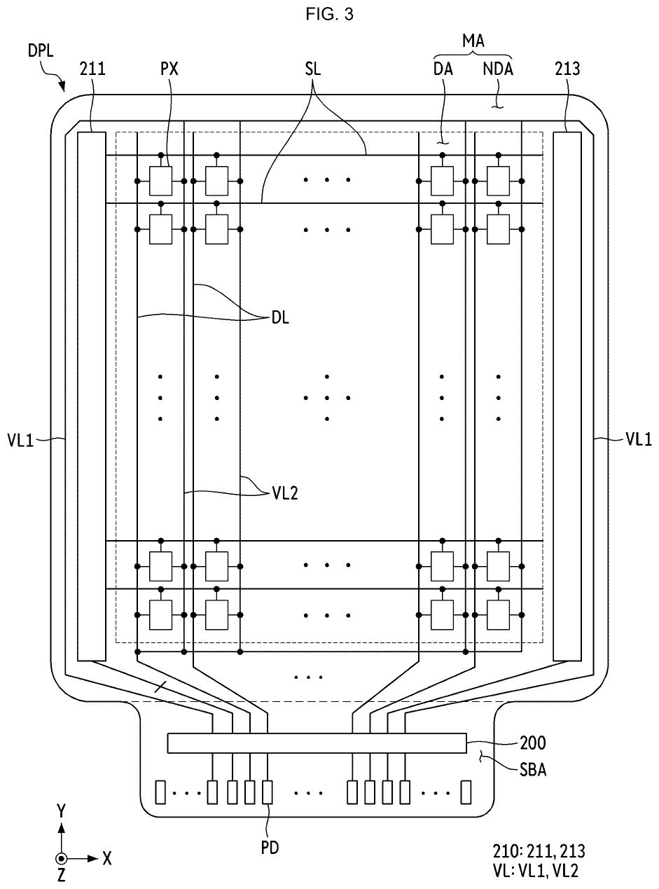

FIG. 3 is a plan view illustrating a display layer in FIG. 2, according to some embodiments of the present disclosure.

Referring to FIG. 3, the display layer DPL according to some embodiments may include a plurality of pixels PX, a plurality of scan lines SL, a plurality of data lines DL, and a plurality of second power lines VL2 in a portion of the main area MA that overlaps the display area DA.

Each of the plurality of pixels PX may be defined as a minimum unit emitting light. Each of the plurality of pixels PX may be connected to at least one scan line SL, at least one data line DL, and at least one power line VL.

The plurality of scan lines SL may supply scan signals applied in each horizontal unit from the scan driver 210 to the plurality of pixels PX. The plurality of scan lines SL may extend in the first direction (e.g., the X-axis direction) and may be spaced apart from each other in the second direction (e.g., the Y-axis direction).

The plurality of data lines DL may supply a data voltage received from the display driver 200 to the plurality of pixels PX. The plurality of data lines DL may extend in the second direction (e.g., the Y-axis direction) and may be spaced apart from each other in the first direction (e.g., the X-axis direction).

The plurality of second power lines VL2 may supply a power voltage received from a first power line VL1 to the plurality of pixels PX. The power voltage may be at least one of a driving voltage, an initialization voltage, and a reference voltage. The plurality of second power lines VL2 may extend in the second direction (e.g., the Y-axis direction) and may be spaced apart from each other in the first direction (e.g., the X-axis direction).

The display layer DPL included in some embodiments may include the first power line VL1 and the scan driver 210 in a portion of the main area MA that overlaps the non-display area NDA.

The first power line VL1 may supply the power voltage received from the display driver 200 to the plurality of pixels PX through the second power line VL2.

The scan driver 210 may include a first scan driver 211 and a second scan driver 213. The first scan driver 211 may be disposed on one side (e.g., a left side) of the display layer DPL, and the second scan driver 213 may be disposed on the other side (e.g., a right side) of the display layer DPL, but the present disclosure is not limited thereto. Each of the first scan driver 211 and the second scan driver 213 may receive a scan control signal from the display driver 200, generate scan signals according to the scan control signal, and output the scan signals to the plurality of scan lines SL.

The display layer DPL included in some embodiments may include a display driver 200 and a plurality of pad electrodes PD in a portion overlapping the sub-area SBA. The plurality of pad electrodes PD may be positioned to be spaced apart from each other in the first direction (e.g., the X-axis direction), and each pad electrode PD may be connected to a different line. The display driver 200 has already been described with reference to FIG. 3 and descriptions thereof may not be repeated.

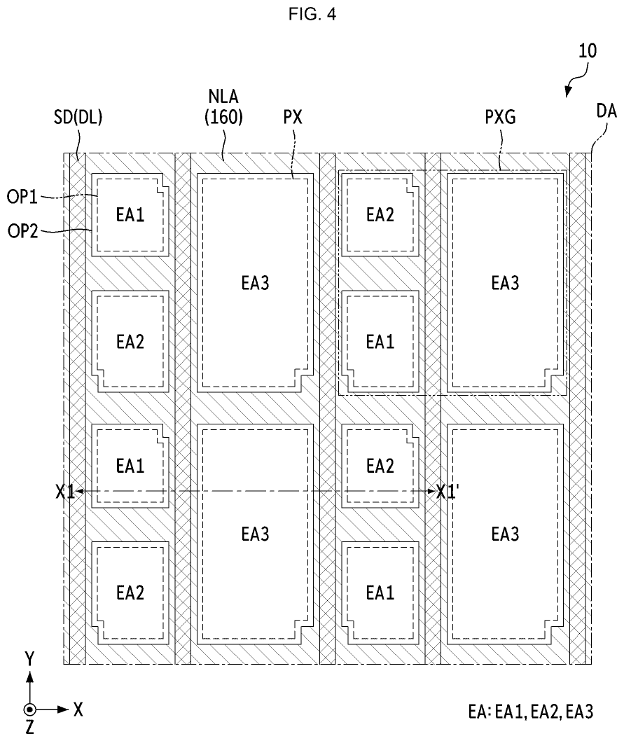

FIG. 4 is a plan view illustrating an arrangement of a plurality of pixels in FIG. 3, according to some embodiments of the present disclosure.

Referring to FIG. 4, the display area DA according to some embodiments may include a light emitting area EA and a non-light emitting area NLA.

The light emitting areas EA may include a first light emitting area EA1, a second light emitting area EA2, and a third light emitting area EA3 that emit light of different colors. Each of the first to third light emitting areas EA1, EA2, and EA3 may each emit red, green, or blue light, and the color of light emitted from each of the first to third light emitting areas EA1, EA2, and EA3 may vary depending on the type of light emitting element (“ED” in FIG. 7), which will be later described in further detail. As an example, the first light emitting area EA1 may emit red light, the second light emitting area EA2 may emit green light, and the third light emitting area EA3 may emit blue light, but the present disclosure is not limited thereto.

The first light emitting area EA1 and the second light emitting area EA2 may be positioned on the same line in the second direction (e.g., the Y-axis direction) and may be spaced apart from each other. The first light emitting area EA1 and the third light emitting area EA3 may be adjacent to each other in the first direction (e.g., the X-axis direction) and may be spaced apart from each other. In addition, the second light emitting area EA2 and the third light emitting area EA3 may be adjacent to each other in the first direction (e.g., the X-axis direction) and may be spaced apart from each other. However, the arrangement of each of the first to third light emitting areas EA1, EA2, and EA3 is not limited thereto and may be freely adjusted according to desired characteristics.

Each of the first to third light emitting areas EA1, EA2, and EA3 may have a quadrangular shape. However, the shape of each of the first to third light emitting areas EA1, EA2, and EA3 is not limited thereto and may be freely adjusted according to desired characteristics.

In some embodiments, at least one first light emitting area EA1, at least one second light emitting area EA2, and at least one third light emitting area EA3 disposed to be adjacent to each other may form one pixel group PXG. The pixel group PXG may be a minimum unit that emits white light. The type and/or number of the first to third light emitting areas EA1, EA2, and EA3 constituting the pixel group PXG may vary depending on the embodiments.

The light emitting area EA may be defined by a first opening OP1 and a second opening OP2. In a plan view, the second opening OP2 may completely surround the first opening OP1, and in a plan view, the second opening OP2 may be completely surrounded by a bank structure 160 positioned in the non-light emitting area NLA. The bank structure 160 will be described below.

The non-light emitting area NLA may be disposed to surround the light emitting area EA. The non-light emitting area NLA may block each light emitted from the plurality of first to third light emitting areas EA1, EA2, and EA3. The non-light emitting area NLA may assist in preventing the light emitted from each of the first to third light emitting areas EA1, EA2, and EA3 from being mixed.

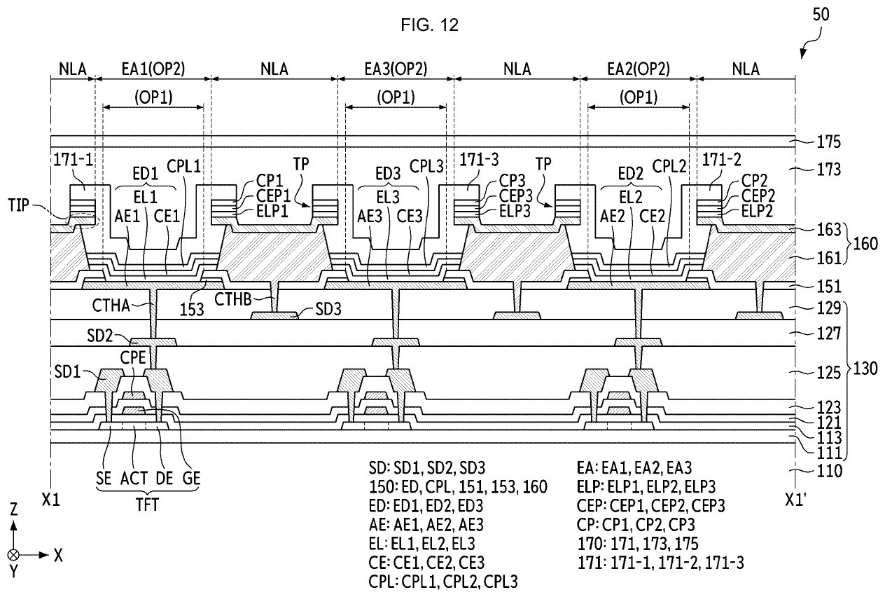

In a plan view, a connection electrode SD may be positioned in a portion overlapping the non-light emitting area NLA. The connection electrode SD may include a first connection electrode (SD1 in FIG. 7), a second connection electrode (SD2 in FIG. 7), and a third connection electrode (SD3 in FIG. 12), which will be later described in further detail.

In a plan view, the connection electrode SD may extend in the second direction (e.g., the Y-axis direction) with a constant or substantially constant width. In a plan view, a plurality of connection electrodes SD positioned to be adjacent to each other may be spaced apart from each other in the first direction (e.g., the X-axis direction) with the light emitting area EA interposed therebetween. In a plan view, the connection electrode SD may be positioned to overlap the data line DL of FIG. 3. The connection electrode SD may receive an electrical signal through the data line DL of FIG. 3.

In a plan view, a bank structure 160 may be positioned in a portion overlapping the non-light emitting area NLA. The bank structure 160 may not overlap the light emitting area EA. The bank structure 160 may be positioned to completely surround the second opening OP2.

In a plan view, the bank structure 160 may overlap the connection electrode SD in the third direction (e.g., the Z-axis direction). In a plan view, the bank structure 160 may entirely cover the connection electrode SD.

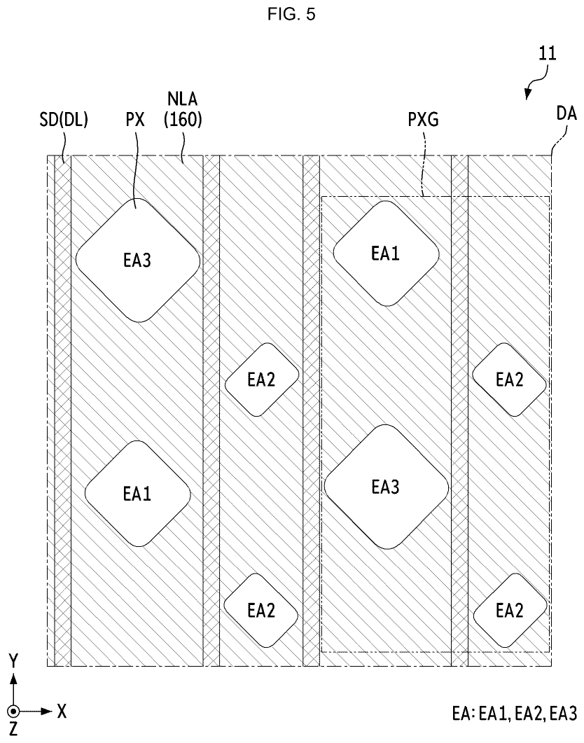

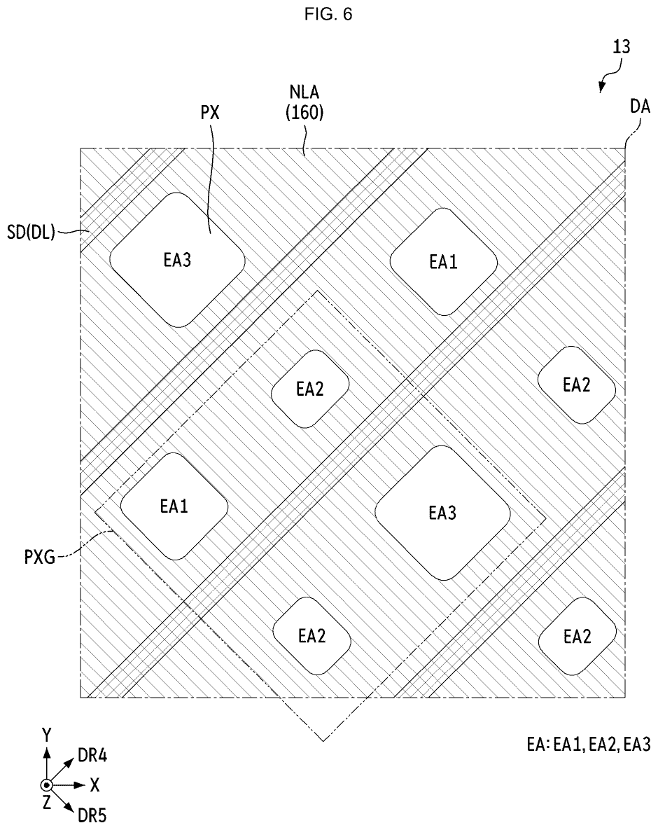

FIGS. 5 and 6 are plan views illustrating an arrangement of a plurality of pixels in FIG. 3, according to some other embodiments of the present disclosure.

Referring to FIGS. 5 and 6, light emitting areas EA included in a display device 11 and a display device 13 may have a different shape and arrangement from the light emitting area EA included in the display device 10. Hereinafter, the commonalities between the light emitting area EA included in the display device 10 and the light emitting areas EA included in the display device 11 and the display devices 13 will be omitted, and the differences therebetween will be later described in further detail.

Each of the first to third light emitting areas EA1, EA2, and EA3 included in the display device 11 and the display device 13 may be disposed in a Pentile™ type formation, for example, a Diamond Pentile™ type formation. For example, the first light emitting area EA1 and the third light emitting area EA3 may be alternately disposed in the first direction (e.g., the X-axis direction) and the second direction (e.g., the Y-axis direction).

The second light emitting area EA2 may be spaced apart from another adjacent second light emitting area EA2 in the first direction (e.g., the X-axis direction) and the second direction (e.g., the Y-axis direction), and may be positioned on the same line as another adjacent second light emitting area EA2. A plurality of second light emitting areas EA2 may be repeatedly disposed along the first direction (e.g., the X-axis direction) and the second direction (e.g., the Y-axis direction). The second light emitting area EA2 may not overlap the adjacent first and third light emitting areas EA1 and EA3 in the first direction (e.g., the X-axis direction) and the second direction (e.g., the Y-axis direction). That is, the second light emitting area EA2 may not be positioned on the same line as the adjacent first and third light emitting areas EA1 and EA3.

The display device 11 and the display device 13 may include at least one first light emitting area EA1, at least two second light emitting areas EA2, and at least one third light emitting area EA3, and may constitute one pixel group PXG. The pixel group PXG may be a minimum unit that emits white light.

In a plan view, a connection electrode SD included in the display device 11 may extend in the second direction (e.g., the Y-axis direction) with a constant or substantially constant width. In a plan view, a plurality of connection electrodes SD positioned to be adjacent to each other may be spaced apart from each other in the first direction (e.g., the X-axis direction) with the light emitting area EA interposed therebetween. In a plan view, the connection electrode SD may be positioned to overlap the data line DL of FIG. 3. The connection electrode SD may receive an electrical signal through the data line DL of FIG. 3. In a plan view, a bank structure 160 included in the display device 11 may entirely cover the connection electrode SD.

In a plan view, the connection electrode SD included in the display device 13 may be positioned in a portion overlapping the non-light emitting area NLA and may not overlap the light emitting area EA. In a plan view, the connection electrode SD may extend in a fourth direction DR4, and the plurality of connection electrodes SD positioned to be adjacent to each other may be spaced apart from each other in a fifth direction DR5 with the light emitting area EA interposed therebetween. In a plan view, the connection electrode SD may be positioned to overlap the data line DL of FIG. 3. The connection electrode SD may receive an electrical signal through the data line DL of FIG. 3.

In a plan view, a bank structure 160 included in the display device 13 may entirely cover the connection electrode SD.

FIG. 7 is a schematic cross-sectional view of the display layer taken along the line X1-X1′ of FIG. 4, according to some embodiments of the present disclosure.

FIG. 7 is a partial cross-sectional view of the display device 10 overlapping the display area DA, and illustrates a cross section of the substrate 110, the thin film transistor layer 130, the display element layer 150, and the thin film encapsulation layer 170. Because the substrate 110 has already been described, it's description may not be repeated will be omitted.

Referring to FIG. 7, the thin film transistor layer 130 may be positioned on the substrate 110. The thin film transistor layer 130 may include a first buffer layer 111, a thin film transistor TFT, a gate insulating layer 113, a first interlayer insulating layer 121, a capacitor electrode CPE, a second interlayer insulating layer 123, a first connection electrode SD1, a first via layer 125, a second connection electrode SD2, and a second via layer 127.

The first buffer layer 111 may be disposed on the substrate 110. The first buffer layer 111 may include an inorganic film capable of preventing or substantially reducing permeation of air or moisture. For example, the first buffer layer 111 may include a plurality of inorganic films alternately stacked.

The thin film transistor TFT may be disposed on the first buffer layer 111, and may constitute a pixel circuit connected to each of the plurality of pixels. As an example, the thin film transistor TFT may be a driving transistor or a switching transistor of the pixel circuit. The thin film transistor TFT may include an active layer ACT, a source electrode SE, a drain electrode DE, and a gate electrode GE.

The active layer ACT may be disposed on the first buffer layer 111. The active layer ACT may overlap the gate electrode GE in the third direction (e.g., the Z-axis direction), and may be insulated from the gate electrode GE by the gate insulating layer 113. In a portion of the active layer ACT, a material of the active layer ACT may become a conductor to form the source electrode SE and the drain electrode DE.

The gate electrode GE may be disposed on the gate insulating layer 113. The gate electrode GE may overlap the active layer ACT with the gate insulating layer 113 interposed therebetween.

The gate insulating layer 113 may be disposed on the active layer ACT. For example, the gate insulating layer 113 may cover the active layer ACT and the first buffer layer 111, and may insulate the active layer ACT and the gate electrode GE from each other. The gate insulating layer 113 may include a contact hole through which the first connection electrode SD1 penetrates.

The first interlayer insulating layer 121 may cover the gate electrode GE and the gate insulating layer 113. The first interlayer insulating layer 121 may include a contact hole through which the first connection electrode SD1 penetrates. The contact hole of the first interlayer insulating layer 121 may be connected to the contact hole of the gate insulating layer 113 and a contact hole of the second interlayer insulating layer 123.

The capacitor electrode CPE may be disposed on the first interlayer insulating layer 121. The capacitor electrode CPE may overlap the gate electrode GE in the third direction (e.g., the Z-axis direction). The capacitor electrode CPE and the gate electrode GE may form a capacitance.

The second interlayer insulating layer 123 may cover the capacitor electrode CPE and the first interlayer insulating layer 121. The second interlayer insulating layer 123 may include a contact hole through which the first connection electrode SD1 penetrates. The contact hole of the second interlayer insulating layer 123 may be connected to the contact hole of the first interlayer insulating layer 121 and the contact hole of the gate insulating layer 113.

The first connection electrode SD1 may be disposed on the second interlayer insulating layer 123. The first connection electrode SD1 may electrically connect the drain electrode DE of the thin film transistor TFT and the second connection electrode SD2 to each other. The first connection electrode SD1 may be inserted into the contact holes formed in the first interlayer insulating layer 121, the second interlayer insulating layer 123, and the gate insulating layer 113 and be in contact with the drain electrode DE of the thin film transistor TFT.

The first via layer 125 may cover the first connection electrode SD1 and the second interlayer insulating layer 123. The first via layer 125 may planarize a lower structure. The first via layer 125 may include a contact hole through which the second connection electrode SD2 penetrates.

The second connection electrode SD2 may be disposed on the first via layer 125. The second connection electrode SD2 may be disposed to overlap the light emitting area EA and the non-light emitting area NLA. The second connection electrode SD2 positioned in a portion overlapping the emitting area EA may be spaced apart from the second connection electrode SD2 positioned in a portion overlapping the non-light emitting area NLA.

The second connection electrode SD2 positioned in a portion overlapping the light emitting area EA may be inserted into a contact hole penetrating through the first via layer 125 and be in contact with the first connection electrode SD1. In addition, the second connection electrode SD2 may be electrically connected to an anode electrode AE inserted into an anode contact hole CTHA penetrating through the second via layer 127. That is, the second connection electrode SD2 may electrically connect the first connection electrode SD1 and the anode electrode AE to each other.

The second connection electrode SD2 positioned in a portion overlapping the non-light emitting area NLA may be electrically connected to the bank structure 160 inserted into a bank contact hole CTHB. The display device 10 according to some embodiments may substantially reduce (e.g., solve) pixel lighting defects caused by contact instability between the cathode electrode CE and the bank structure 160 by electrically connecting the second connection electrode SD2 positioned in a portion overlapping the non-light emitting area NLA and the bank structure 160 to each other. Further details will be described later.

The second via layer 127 may cover the second connection electrode SD2 and the first via layer 125. The second via layer 127 may be penetrated by the anode contact hole CTHA and the bank contact hole CTHB.

The display element layer 150 according to some embodiments may be disposed on the thin film transistor layer 130. The display element layer 150 may include a light emitting element ED, a capping layer CPL, a pixel defining layer 151, a residual pattern 153, and a bank structure 160.

The light emitting element ED according to some embodiments may include a first light emitting element ED1 disposed in the first light emitting area EA1, a second light emitting element ED2 disposed in the second light emitting area EA2, and a third light emitting element ED3 disposed in the third light emitting area EA3.

The light emitting element ED may include an anode electrode AE, a light emitting layer EL, and a cathode electrode CE. As an example, the first light emitting element ED1 may include a first anode electrode AE1, a first light emitting layer EL1, and a first cathode electrode CE1, the second light emitting element ED2 may include a second anode electrode AE2, a second light emitting layer EL2, and a second cathode electrode CE2, and the third light emitting element ED3 may include a third anode electrode AE3, a third light emitting layer EL3, and a third cathode electrode CE3.

Each of the first to third light emitting elements ED1, ED2, and ED3 may emit light of different colors depending on the material of the light emitting layer EL. For example, the first light emitting element ED1 may emit red light, the second light emitting element ED2 may emit green light, and the third light emitting element ED3 may emit blue light.

The anode electrode AE according to some embodiments may be disposed on the second via layer 127. The anode electrode AE may be connected to the second connection electrode SD2 through the anode contact hole CTHA, and may be electrically connected to the drain electrode DE of the thin film transistor TFT through the first connection electrode SD1.

The anode electrode AE may include a first anode electrode AE1 positioned in the first light emitting area EA1, a second anode electrode AE2 positioned in the second light emitting area EA2, and a third anode electrode AE3 positioned in the third light emitting area EA3. The first to third anode electrodes AE1, AE2, and AE3 may be disposed to be spaced apart from each other on the second via layer 127.

The pixel defining layer 151 according to some embodiments may be positioned on the second via layer 127 and the anode electrode AE. The pixel defining layer 151 may define the first opening OP1. The pixel defining layer 151 may expose the anode electrode AE in a portion overlapping the first opening OP1.

The pixel defining layer 151 may include an inorganic insulating material. As an example, the pixel defining layer 151 may include aluminum oxide, titanium oxide, tantalum oxide, hafnium oxide, zinc oxide, silicon oxide, silicon nitride, silicon oxynitride, and/or the like.

The bank structure 160 according to some embodiments may be positioned on the pixel defining layer 151. The bank structure 160 may define the second opening OP2. The bank structure 160 may include a first bank layer 161 and a second bank layer 163 that include different metal materials and perform different functions.

The bank structure 160 may include a tip (or protrusion) positioned in a portion overlapping the light emitting area EA. In general, in a high-resolution display device, the spacing (e.g., gap) between adjacent ones of the plurality of light emitting elements ED may be narrow. Therefore, it may be difficult to form the plurality of light emitting elements ED included in the high-resolution display device using a mask during the manufacturing process. In the display device 10 according to some embodiments, as the bank structure 160 includes the tip, the plurality of light emitting elements ED that overlap each of the first to third light emitting areas EA1, EA2, and EA3 may be formed without a separate fine metal mask during the manufacturing process. Therefore, the display device 10 according to some embodiments may be provided as a high-resolution display device 10.

The light emitting layer EL according to some embodiments may be disposed on the anode electrode AE. The light emitting layer EL may be an organic light emitting layer made of an organic material, and may be formed on the anode electrode AE through a deposition process. In the light emitting layer EL, when the thin film transistor TFT applies a set or predetermined voltage to the anode electrode AE and the cathode electrode CE receives a common voltage or a cathode voltage, each of the holes and electrons may move to the light emitting layer EL through a hole transporting layer and an electron transporting layer, and the holes and electrons may be combined with each other in the light emitting layer EL to emit light.

The light emitting layer EL may include a first light emitting layer EL1, a second light emitting layer EL2, and a third light emitting layer EL3 disposed in the first to third light emitting areas EA1, EA2, and EA3, respectively. As an example, the first light emitting layer EL1 may be a light emitting layer that emits red light, the second light emitting layer EL2 may be a light emitting layer that emits green light, and the third light emitting layer EL3 may be a light emitting layer that emits blue light, but the present disclosure is not limited thereto.

The residual pattern 153 according to some embodiments may be positioned between the anode electrode AE and the pixel defining layer 151 in the third direction (e.g., the Z-axis direction). The residual pattern 153 may overlap the tip of the bank structure 160 in the third direction (e.g., the Z-axis direction).

The cathode electrode CE according to some embodiments may be disposed on the light emitting layer EL. The cathode electrode CE may include a transparent conductive material so that light generated in the light emitting layer EL may be emitted.

The cathode electrode CE may include a first cathode electrode CE1, a second cathode electrode CE2, and a third cathode electrode CE3. The first cathode electrode CE1 may be disposed on the first light emitting layer EL1 in the first light emitting area EA1, the second cathode electrode CE2 may be disposed on the second light emitting layer EL2 in the second light emitting area EA2, and the third cathode electrode CE3 may be disposed on the third light emitting layer EL3 in the third light emitting area EA3.

The first to third cathode electrodes CE1, CE2, and CE3 may be spaced apart from each other with the bank structure 160 interposed therebetween. Each of the first cathode electrode CE1, the second cathode electrode CE2, and the third cathode electrode CE3 may be in contact with the first bank layer 161 of the bank structure 160, and may be electrically connected to each other through the first bank layer 161.

In the display device 10 according to some embodiments, the cathode electrode CE may receive a common voltage or a low-potential voltage. When the anode electrode AE receives a voltage corresponding to the data voltage and the cathode electrode CE receives the low-potential voltage, the light emitting layer EL may emit light as a potential difference is formed between the anode electrode AE and the cathode electrode CE. In this case, the first to third cathode electrodes CE1, CE2, and CE3 positioned to be spaced apart from each other with the bank structure 160 interposed therebetween may be electrically connected to each other through the bank structure 160. However, in some cases, lighting defects may occur in some pixels included in the display device 10 due to contact instability between the cathode electrode CE and the bank structure 160.

The display device 10 according to some embodiments may substantially reduce (e.g., solve) pixel lighting defects caused by contact instability between the cathode electrode CE and the bank structure 160 by applying voltages of different polarities to each of the second connection electrodes SD2 positioned to overlap the plurality of non-light emitting areas NLA adjacent to each other with the light emitting area EA interposed therebetween. As an example, the display device 10 according to some embodiments may stably maintain an electrical connection between the cathode electrode CE and the bank structure 160 by using different potential differences by applying about +5 V to the second connection electrode SD2 overlapping the non-light emitting area NLA on one side and applying about −5 V to the second connection electrode SD2 overlapping the non-light emitting area NLA on the other side that are positioned with the light emitting area EA interposed therebetween. Accordingly, the display device 10 according to some embodiments may substantially reduce (e.g., solve) pixel lighting defects caused by contact instability of the bank structure 160.

The voltage applied to the second connection electrode SD2 may be applied through the data line DL illustrated in FIGS. 3 to 6. However, the voltage applied to the second connection electrode SD2 is not limited thereto and may be applied through various lines surrounding the pixel PX illustrated in FIG. 3. Accordingly, the display device 10 according to some embodiments may provide a display device 10 with excellent reliability.

The capping layer CPL according to some embodiments may be positioned on the cathode electrode CE. The capping layer CPL may prevent the plurality of light emitting elements ED from being damaged by external air, and may prevent the plurality of light emitting elements ED from being peeled off during the manufacturing process of the display device 10.

The capping layer CPL may include a first capping layer CPL1 disposed in a portion overlapping the first light emitting area EA1, a second capping layer CPL2 disposed in a portion overlapping the second light emitting area EA2, and a third capping layer CPL3 disposed in a portion overlapping the third light emitting area EA3. The first to third capping layers CPL1, CPL2, and CPL3 may be spaced apart from each other with the pixel defining layer 151 interposed therebetween.

The capping layer CPL according to some embodiments may include an inorganic insulating material. As an example, the capping layer CPL may include aluminum oxide, titanium oxide, tantalum oxide, hafnium oxide, zinc oxide, silicon oxide, silicon nitride, silicon oxynitride, and/or the like.

The organic pattern ELP according to some embodiments may be positioned on the bank structure 160. The organic pattern ELP may be disposed to surround the first opening OP1 on the second bank layer 163. The organic pattern ELP may include the same or substantially the same material as each light emitting layer EL.

The organic pattern ELP may include a first organic pattern ELP1, a second organic pattern ELP2, and a third organic pattern ELP3. As an example, the first organic pattern ELP1 may include the same or substantially the same material as the first light emitting layer EL1, the second organic pattern ELP2 may include the same or substantially the same material as the second light emitting layer EL2, and the third organic pattern ELP3 may include the same or substantially the same material as the third light emitting layer EL3. As the bank structure 160 includes the tip during the manufacturing process of the display device 10, the organic pattern ELP may be a trace formed by being disconnected from the light emitting layer EL.

The electrode pattern CEP according to some embodiments may be positioned on the organic pattern ELP. The electrode pattern CEP may be disposed to surround the first opening OP1 on the organic pattern ELP. Each electrode pattern CEP may include the same or substantially the same material as the cathode electrode CE.

The electrode pattern CEP may include a first electrode pattern CEP1, a second electrode pattern CEP2, and a third electrode pattern CEP3. As an example, the first electrode pattern CEP1 may include the same or substantially the same material as the first cathode electrode CE1, the second electrode pattern CEP2 may include the same or substantially the same material as the second cathode electrode CE2, and the third electrode pattern CEP3 may include the same or substantially the same material as the third cathode electrode CE3. As the bank structure 160 includes the tip during the manufacturing process of the display device 10, the electrode pattern CEP may be a trace formed by being disconnected from the cathode electrode CE.

The capping pattern CP according to some embodiments may be positioned on the electrode pattern CEP. The capping pattern CP may be disposed to surround the first opening OP1 on the electrode pattern CEP. Each capping pattern CP may include the same or substantially the same material as the capping layer CPL.

The capping pattern CP may include a first capping pattern CP1, a second capping pattern CP2, and a third capping pattern CP3. As an example, the first capping pattern CP1 may include the same or substantially the same material as the first capping layer CPL1, the second capping pattern CP2 may include the same or substantially the same material as the second capping layer CPL2, and the third capping pattern CP3 may include the same or substantially the same material as the third capping layer CPL3. As the bank structure 160 includes the tip during the manufacturing process of the display device 10, the capping pattern CP may be a trace formed by being disconnected from the capping layer CPL.

The organic pattern ELP, the electrode pattern CEP, and the capping pattern CP according to some embodiments may have a trench portion TP in a portion overlapping the non-light emitting area NLA. During the manufacturing process of the display device 10, the material forming the organic pattern ELP, the material forming the electrode pattern CEP, and the material forming the capping pattern CP may be formed to entirely cover the second bank layer 163 positioned in a portion overlapping the non-light emitting area NLA, and may be then formed in the currently illustrated shape by removing a portion thereof through a subsequent etching process. That is, the organic pattern ELP, the electrode pattern CEP, and the capping pattern CP including the trench portion TP in a portion overlapping the non-light emitting area NLA may be an indication that the organic pattern ELP, the electrode pattern CEP, and the capping pattern CP have undergone an etching process during the manufacturing process of the display device 10.

The thin film encapsulation layer 170 according to some embodiments may be positioned on the display element layer 150. The thin film encapsulation layer 170 may prevent oxygen or moisture from permeating into the display element layer 150 or substantially reduce such permeation and protect the display element layer 150 from foreign substances such as dust. The thin film encapsulation layer 170 may include a first encapsulation layer 171, a second encapsulation layer 173, and a third encapsulation layer 175 that are sequentially stacked. The first encapsulation layer 171 and the third encapsulation layer 175 may include one or more inorganic insulating materials, and the second encapsulation layer 173 may include a polymer-based organic material.

The first encapsulation layer 171 according to some embodiments may include first to third inorganic layers 171-1, 171-2, and 171-3. The first to third inorganic layers 171-1, 171-2, and 171-3 may be positioned in portions overlapping the first to third light emitting areas EA1, EA2, and EA3, respectively. As an example, the first inorganic layer 171-1 may cover the first capping layer CPL1 and the first capping pattern CP1 in a portion overlapping the first light emitting area EA1, the second inorganic layer 171-2 may cover the second capping layer CPL2 and the second capping pattern CP2 in the portion overlapping the second light emitting area EA2, and the third inorganic layer 171-3 may cover the third capping layer CPL3 and the third capping pattern CP3 in a portion overlapping the third light emitting area EA3. Each of the first to third inorganic layers 171-1, 171-2, and 171-3 may be spaced apart from each other in a portion overlapping the non-light emitting area NLA.

It is illustrated in the drawing that the first to third inorganic layers 171-1, 171-2, and 171-3 are formed at the same layer, but the first to third inorganic layers 171-1, 171-2, and 171-3 may be formed in different processes. For example, the first inorganic layer 171-1 may be formed after forming the first capping layer CPL1, the second inorganic layer 171-2 may be formed after forming the second capping layer CPL2, and the third inorganic layer 171-3 may be formed after forming the third capping layer CPL3.

The first to third inorganic layers 171-1, 171-2, and 171-3 according to some embodiments may include a trench portion TP in a portion overlapping the non-light emitting area NLA. During the manufacturing process of the display device 10, the material forming the first to third inorganic layers 171-1, 171-2, and 171-3 may be formed to entirely cover the second bank layer 163 positioned in the portion overlapping the non-light emitting area NLA, and may be then formed in the currently illustrated shape by removing a portion thereof through a subsequent etching process. That is, the first to third inorganic layers 171-1, 171-2, and 171-3 including the trench portion TP in the portion overlapping the non-light emitting area NLA may be an indication that the first to third inorganic layers 171-1, 171-2, and 171-3 have undergone an etching process in the manufacturing process of the display device 10.

The second encapsulation layer 173 according to some embodiments may be positioned on the first encapsulation layer 171. The second encapsulation layer 173 may planarize a level difference formed by the first inorganic layer 171-1 in a portion overlapping the first light emitting area EA1 and the non-light emitting area NLA.

The second encapsulation layer 173 may include a polymer-based material. As an example, the second encapsulation layer 173 may include an acrylic resin, a silicone resin, a silicone acrylic resin, an epoxy resin, and/or the like. The second encapsulation layer 173 may be formed by curing a monomer or applying a polymer.

The third encapsulation layer 175 according to some embodiments may be positioned on the second encapsulation layer 173 and entirely cover the second encapsulation layer 173. The third encapsulation layer 175 may include an inorganic material and may include the same or substantially the same material as the first encapsulation layer 171. Redundant descriptions may not be repeated.

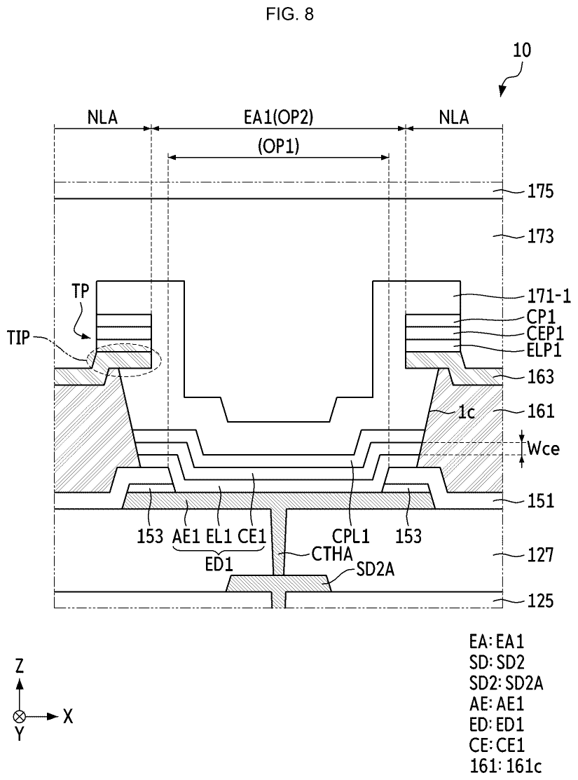

FIG. 8 is an enlarged cross-sectional view of a display element layer and a thin film encapsulation layer overlapping a first light emitting area in FIG. 7, according to some embodiments of the present disclosure.

Referring to FIG. 8, the second connection electrode SD2 according to some embodiments may include a first portion SD2A positioned in a portion overlapping the light emitting area EA. The first portion SD2A of the second connection electrode SD2 may not overlap the non-light emitting area NLA. The first portion SD2A may be electrically connected to the anode electrode AE inserted into the anode contact hole CTHA.

The pixel defining layer 151 according to some embodiments may be spaced apart from the first anode electrode AE1 in the third direction (e.g., the Z-axis direction) in a portion overlapping the second opening OP2. The residual pattern 153 may be positioned in a portion where the pixel defining layer 151 and the first anode electrode AE1 are spaced apart from each other. The residual pattern 153 may be positioned to overlap the tip of the second bank layer 163 in the third direction (e.g., the Z-axis direction).

The display device 10 may include a sacrificial layer between the pixel defining layer 151 and the anode electrode AE during the manufacturing process. The sacrificial layer may be disposed between the pixel defining layer 151 and the anode electrode AE, and then partially removed by a subsequent etching process. In this case, a portion of the sacrificial layer that has not been removed may remain as the residual pattern 153 between the pixel defining layer 151 and the anode electrode AE. The residual pattern 153 may be in contact with the pixel defining layer 151, the anode electrode AE, and the light emitting layer EL, and may be entirely surrounded by the pixel defining layer 151, the anode electrode AE, and the light emitting layer EL.

The first bank layer 161 according to some embodiments may be positioned on the pixel defining layer 151. The first bank layer 161 may include a metal with high electrical conductivity. As an example, the first bank layer 161 may include aluminum (AI).

In some embodiments, the first bank layer 161 may include a side surface 1c. The side surface 1c is one surface facing the first opening OP1, and may be positioned to be more recessed in a direction toward the non-light emitting area NLA, that is, on one side in the first direction (e.g., the X-axis direction) than the pixel defining layer 151.

The first cathode electrode CE1 according to some embodiments may be in contact with the side surface 1c of the first bank layer 161. In the display device 10 according to some embodiments, as a contact area Wce between the cathode electrode CE and the side surface 1c increases, electrical resistance formed between the cathode electrode CE and the bank structure 160 may be lowered. The area Wce where the cathode electrode CE is in contact with the side surface 1c may be adjusted depending on the desired characteristics of the display device 10.

It is illustrated in the drawing that the first light emitting layer EL1 and the first capping layer CPL1 are in contact with the side surface 1c of the first bank layer 161, but the present disclosure is not limited thereto. Depending on process conditions, the first light emitting layer EL1 and the first capping layer CPL1 may be in non-contact with the side surface 1c.

The second bank layer 163 according to some embodiments may be positioned on the first bank layer 161. The second bank layer 163 may include a material with a lower etch rate than the first bank layer 161. As an example, the second bank layer 163 may include titanium Ti.

The second bank layer 163 may include a tip that protrudes more toward the first opening OP1 than the side surface 1c of the first bank layer 161. An undercut may be formed between the tip of the second bank layer 163 and the side surface 1c of the first bank layer 161. In the display device 10 according to some embodiments, because the second bank layer 163 includes the tip, the light emitting elements ED spaced apart from each other may be formed in portions overlapping each light emitting area EA without a separate fine metal mask during the manufacturing process.

The first organic pattern ELP1, the first electrode pattern CEP1, and the first capping pattern CP1 according to some embodiments may be positioned to overlap the tip of the second bank layer 163 and the residual pattern 153 in the third direction (e.g., the Z-axis direction).

The first inorganic layer 171-1 according to some embodiments may entirely cover the light emitting element ED1 in a portion overlapping the first opening OP1, and may entirely cover the side surface 1c of the first bank layer 161 and the tip of the second bank layer 163 in a portion overlapping the second opening OP2. In addition, the first inorganic layer 171-1 according to some embodiments may cover a portion of the first organic pattern ELP1, a portion of the first electrode pattern CEP1, and a portion of the first capping pattern CP1 in a portion overlapping the non-light emitting area NLA.

The second encapsulation layer 173 according to some embodiments may be positioned on the first inorganic layer 171-1 and may entirely cover the first inorganic layer 171-1. In addition, the second encapsulation layer 173 may entirely cover the second bank layer 163 and may be in contact with the second bank layer 163 in a portion overlapping the non-light emitting area NLA. The second encapsulation layer 173 may also completely cover the trench portion TP formed by the first organic pattern ELP1, the first electrode pattern CEP1, the first capping pattern CP1, and the first inorganic layer 171-1.

Although the display element layer 150 and the thin film encapsulation layer 170 positioned in a portion overlapping the first light emitting area EA1 are illustrated and described for convenience of explanation, the structure and characteristics of the display element layer 150 and the thin film encapsulation layer 170 positioned in portions overlapping the second light emitting area EA2 and the third light emitting area EA3 may be the same as those described above.

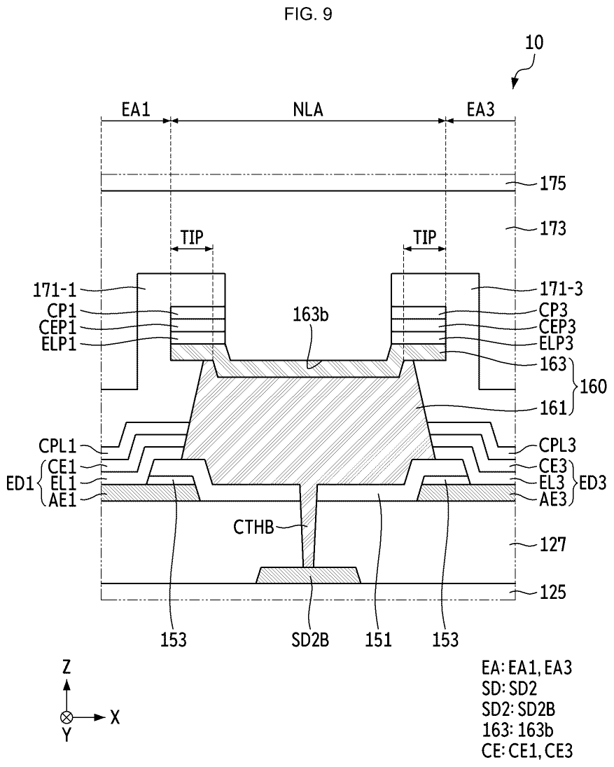

FIG. 9 is an enlarged cross-sectional view of a display element layer and a thin film encapsulation layer overlapping a non-light emitting area positioned between the first light emitting area and a third light emitting area in FIG. 8, according to some embodiments of the present disclosure.

Referring to FIG. 9, the second connection electrode SD2 according to some embodiments may include a second portion SD2B positioned in a portion overlapping the non-light emitting area NLA. The second portion SD2B of the second connection electrode SD2 may not overlap the light emitting area EA. The second portion SD2B may be electrically connected to the bank structure 160 inserted into the bank contact hole CTHB.

The bank contact hole CTHB according to some embodiments may penetrate through the pixel defining layer 151 and the second via layer 127. The pixel defining layer 151 may be positioned to surround the bank contact hole CTHB in a portion overlapping the non-light emitting area NLA.

The first bank layer 161 according to some embodiments may be inserted into the bank contact hole CTHB, and as a result, the second portion SD2B of the second connection electrode SD2 and the first bank layer 161 may be electrically connected to each other. As described above, the cathode electrode CE according to some embodiments may be electrically connected through the first bank layer 161. Therefore, the cathode electrode CE according to some embodiments may be electrically connected to the second portion SD2B of the second connection electrode SD2 through the first bank layer 161.

The display device 10 according to some embodiments may substantially reduce (e.g., solve) pixel lighting defects caused by contact instability between the cathode electrode CE and the first bank layer 161 by electrically connecting the cathode electrode CE, the first bank layer 161, and the second connection electrode SD2. Redundant description may not be repeated.

The first light emitting element ED1 and the third light emitting element ED3 according to some embodiments may be spaced apart from each other with the pixel defining layer 151 and the first bank layer 161 interposed therebetween. In addition, the first capping layer CPL1 and the third capping layer CPL3 according to some embodiments may be spaced apart from each other with the pixel defining layer 151 and the first bank layer 161 interposed therebetween.

The second bank layer 163 according to some embodiments may include tips that protrude more on both sides toward the light emitting area EA than the first bank layer 161. The first organic pattern ELP1, the first electrode pattern CEP1, and the first capping pattern CP1 may be positioned on the tip that protrudes toward the first light emitting area EA1, and the third organic pattern ELP3, the third electrode pattern CEP3, and the third capping pattern CP3 may be positioned on the tip that protrudes toward the third light emitting area EA3.

The first organic pattern ELP1, the first electrode pattern CEP1, and the first capping pattern CP1 may be spaced apart from the third organic pattern ELP3, the third electrode pattern CEP3, and the third capping pattern CP3 in the first direction (e.g., the X-axis direction) with the second encapsulation layer 173 interposed therebetween in a portion overlapping the non-light emitting area NLA.

The first inorganic layer 171-1 and the third inorganic layer 171-3 according to some embodiments may be spaced apart from each other with the bank structure 160 interposed therebetween. The first inorganic layer 171-1 and the third inorganic layer 171-3 may be spaced apart from each other in the first direction (e.g., the X-axis direction) with the second encapsulation layer 173 interposed therebetween in a portion overlapping the non-light emitting area NLA.

In the portion overlapping the non-light emitting area NLA, a portion of an upper surface 163b of the second bank layer 163 may be exposed, and the exposed portion of the upper surface 163b of the second bank layer 163 may be in contact with the second encapsulation layer 173.

Although the display element layer 150 and the thin film encapsulation layer 170 positioned in the portions overlapping the first light emitting area EA1 and the third light emitting area EA3 are illustrated and described for convenience of explanation, the structure and characteristics of the display element layer 150 and the thin film encapsulation layer 170 positioned in a portion overlapping the second light emitting area EA2 may be the same as those described above.

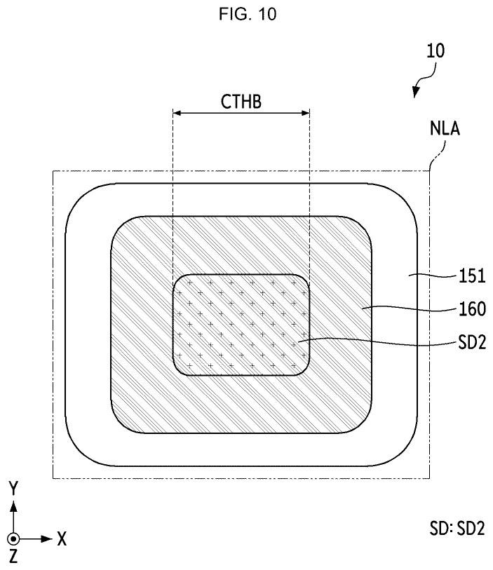

FIG. 10 is a plan view illustrating an arrangement of a connection electrode, a pixel defining layer, and a bank structure in FIG. 9, according to some embodiments of the present disclosure.

Referring to FIG. 10, in a plan view, the second connection electrode SD2 positioned to overlap the non-light emitting area NLA may be exposed at a portion overlapping the bank contact hole CTHB.

In a plan view, the pixel defining layer 151 positioned to overlap the non-light emitting area NLA may expose the bank contact hole CTHB, and may be positioned to surround an edge of the bank contact hole CTHB. In other words, in a plan view, the pixel defining layer 151 may be positioned to entirely surround the second connection electrode SD2.

In a plan view, the bank structure 160 positioned to overlap the non-light emitting area NLA may cover the second connection electrode SD2 and the pixel defining layer 151. For example, in a plan view, the bank structure 160 may completely cover the second connection electrode SD2 and may cover a portion of the pixel defining layer 151.

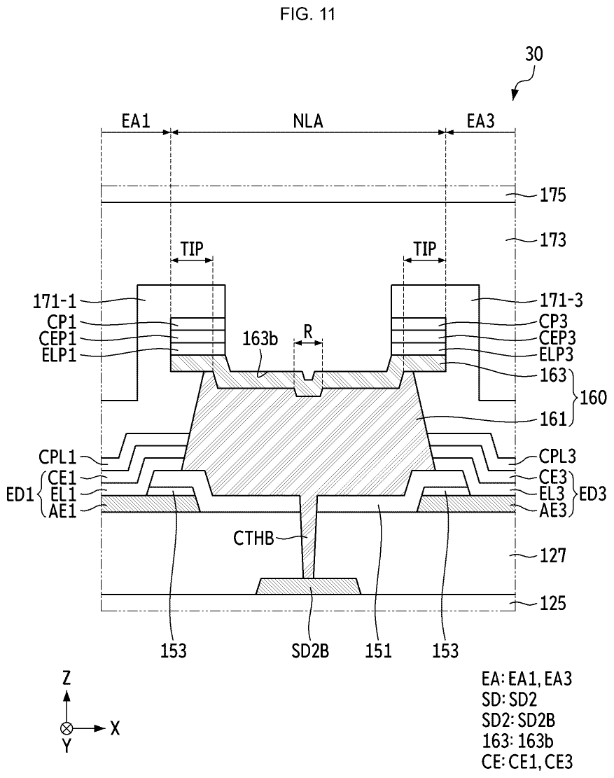

FIG. 11 is an enlarged cross-sectional view of a display element layer and a thin film encapsulation layer overlapping a non-light emitting area positioned between the first light emitting area and the third light emitting area in FIG. 8 according to still other embodiments of the present disclosure.

Referring to FIG. 11, the shape of the second bank layer 163 included in the display device 30 may be different from the shape of the second bank layer 163 included in the display device 10. Hereinafter, a description of the common structure of the display device 10 and the display device 30 may not be repeated and the differences thereof will be described.

The second bank layer 163 included in the display device 30 may include a recessed portion R in a portion overlapping the non-light emitting area NLA. The recessed portion R may refer to a portion where a portion of the second bank layer 163 is recessed in a direction toward the pixel defining layer 151. The recessed portion R included in the second bank layer 163 may be formed as the first bank layer 161 fills the bank contact hole CTHB. The recessed portion R included in the second bank layer 163 may be positioned to overlap the second portion SD2B of the second connection electrode SD2 and the bank contact hole CTHB in the third direction (e.g., the Z-axis direction).

The recessed portion R included in the second bank layer 163 may be positioned between the first organic pattern ELP1, the first electrode pattern CEP1, the first capping pattern CP1, and the first inorganic layer 171-1 and the third organic pattern ELP3, the third electrode pattern CEP3, the third capping pattern CP3, and the third inorganic layer 171-3.

The recessed portion R included in the second bank layer 163 may be filled with the second encapsulation layer 173. Other redundant descriptions may not be repeated.

The display device 30 according to some embodiments may substantially reduce (e.g., solve) pixel lighting defects caused by contact instability between the cathode electrode CE and the first bank layer 161 by electrically connecting the cathode electrode CE, the first bank layer 161, and the second connection electrode SD2. Other redundant descriptions may not be repeated.

FIG. 12 is a schematic cross-sectional view taken along the line X1-X1′ of FIG. 4, according to still other embodiments of the present disclosure.

Referring to FIG. 12, a display device 50 may be different from the display device 10 in that it includes a third connection electrode SD3. Hereinafter, a description of the common structure of the display device 10 and the display device 50 may not be repeated and the differences thereof will be described.

A second connection electrode SD2 included in the display device 50 may be disposed on the first via layer 125. The second connection electrode SD2 may be positioned in a portion overlapping the light emitting area EA and may not overlap the non-light emitting area NLA.

The second connection electrodes SD2 positioned in portions overlapping the first to third light emitting areas EA1, EA2, and EA3, respectively, may be spaced apart from each other. The second connection electrode SD2 may be inserted into the contact hole formed in the first via layer 125 and be in contact with the first connection electrode SD1. In addition, the second connection electrode SD2 may be in contact with the anode electrode AE inserted through the anode contact hole CTHA. Therefore, the second connection electrode SD2 may electrically connect the first connection electrode SD1 and the anode electrode AE to each other.

The second via layer 127 may cover the second connection electrode SD2 and the first via layer 125. The second via layer 127 may include the anode contact hole CTHA penetrating through the second via layer 127.

A third connection electrode SD3 included in the display device 50 may be disposed on the second via layer 127. The third connection electrode SD3 may be positioned in a portion overlapping the non-light emitting area NLA and may not overlap the light emitting area EA. The third connection electrodes SD3 may be spaced apart from each other in a portion overlapping each non-light emitting area NLA. The third connection electrode SD3 may include the same or substantially the same material as that of the first connection electrode SD1 and the second connection electrode SD2.

The display device 50 may be easily manufactured as a high-resolution display device 50 by forming the connection electrode SD connected to the anode electrode AE in a separate layer from the connection electrode SD connected to the bank structure 160.

The bank contact hole CTHB included in the display device 50 may penetrate through the pixel defining layer 151 and the third via layer 129. The pixel defining layer 151 may be positioned to surround the bank contact hole CTHB in a portion overlapping the non-light emitting area NLA.

The third connection electrode SD3 included in the display device 50 may be in contact with the bank structure 160 through the bank contact hole CTHB. For example, the first bank layer 161 included in the display device 50 may be inserted into the bank contact hole CTHB, and as a result, the third connection electrode SD3 and the first bank layer 161 may be electrically connected to each other. A cathode electrode CE included in the display device 50 may be electrically connected to the first bank layer 161. Therefore, the cathode electrode CE included in the display device 50 may be electrically connected to the third connection electrode SD3 through the first bank layer 161.

The display device 50 may substantially reduce (e.g., solve) pixel lighting defects caused by contact instability between the cathode electrode CE and the first bank layer 161 by electrically connecting the cathode electrode CE, the first bank layer 161, and the third connection electrode SD3. Other redundant descriptions may not be repeated.

It should be understood that embodiments described herein should be considered in a descriptive sense and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the present disclosure as defined by the following claims and equivalents thereof.

What is claimed is:

1. A display device comprising:
a substrate comprising a light emitting area and a non-light emitting area;
a connection electrode positioned on the substrate;
an anode electrode positioned on the connection electrode in a portion overlapping the light emitting area;
a cathode electrode on the anode electrode;
a pixel defining layer positioned on the connection electrode in a portion overlapping the non-light emitting area and defining a first opening; and
a bank structure positioned on the pixel defining layer and comprising a first bank layer and a second bank layer,
wherein the first bank layer is electrically connected to the connection electrode through a bank contact hole.

2. The display device of claim 1, wherein the second bank layer comprises a tip that protrudes more toward the first opening than a side surface of the first bank layer facing the light emitting area.

3. The display device of claim 2, wherein the connection electrode comprises:
a first portion overlapping the light emitting area and not overlapping the non-light emitting area; and
a second portion overlapping the non-light emitting area and not overlapping the light emitting area.

4. The display device of claim 3, wherein the first portion and the second portion are spaced apart from each other.

5. The display device of claim 4, wherein the connection electrode comprises a conductive metal.

6. The display device of claim 4, wherein the first portion and the second portion are formed at the same layer in a direction parallel to the substrate.

7. The display device of claim 4, wherein the first portion and the second portion are formed on different layers in a direction parallel to the substrate.

8. The display device of claim 4, wherein the first bank layer is in contact with the second portion through the bank contact hole, and
wherein the anode electrode is in contact with the first portion through an anode contact hole.

9. The display device of claim 3, wherein the cathode electrode is in contact with the first bank layer, and
wherein the cathode electrode and the first bank layer are electrically connected to each other.

10. The display device of claim 9, wherein the cathode electrode is electrically connected to the second portion through the first bank layer.

11. The display device of claim 2, wherein the first bank layer has higher electrical conductivity than the second bank layer.

12. The display device of claim 11, wherein the first bank layer comprises aluminum, and the second bank layer comprises titanium.

13. The display device of claim 1, wherein the pixel defining layer is positioned to surround the bank contact hole.

14. The display device of claim 2, wherein a residual pattern is positioned between the pixel defining layer and the anode electrode in a direction perpendicular to the substrate, and
wherein the residual pattern overlaps a tip of the second bank layer in the direction perpendicular to the substrate.

15. The display device of claim 2, wherein the second bank layer comprises a recessed portion recessed in a direction toward the pixel defining layer in a portion overlapping the non-light emitting area.

16. The display device of claim 15, wherein the recessed portion of the second bank layer overlaps the bank contact hole and the connection electrode in a direction perpendicular to the substrate.

17. A display device comprising:
a substrate comprising a light emitting area and a non-light emitting area;
a connection electrode positioned on the non-light emitting area of the substrate and not overlapping the light emitting area;
a pixel defining layer positioned on the connection electrode and defining a first opening;
a bank contact hole penetrating through the pixel defining layer; and
a bank structure positioned on the pixel defining layer, defining a second opening, and filling the bank contact hole,
wherein in a plan view, the bank structure completely covers the connection electrode.

18. The display device of claim 17, wherein in a plan view, the bank structure covers a portion of the pixel defining layer.

19. The display device of claim 18, wherein in a plan view, the pixel defining layer exposes the bank contact hole, and in a plan view, the pixel defining layer completely surrounds the connection electrode.

20. The display device of claim 19, wherein in a plan view, the second opening completely surrounds the first opening.
